(19) United States
(12) Patent Application Publication
(10) Pub. No.: US 2006/0091510 A1
(43) Pub. Date: May 4, 2006

(54) Probe card interposer

(75) Inventors: An-Hong Liu, Tainan City (TW); Yeong-Her Wang, Tainan City (TW); Yao-Jung Lee, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS TECHNOLOGIES (Bermuda) LTD.; ChipMOS TECHNOLOGIES INC.

(21) Appl. No.: 11/076,935

(22) Filed: Mar. 11, 2005

(30) Foreign Application Priority Data
Nov. 3, 2004 (TW) 093203727
Nov. 3, 2004 (TW) 093106560

(51) Int. Cl. H01L 23/02

(52) U.S. Cl. 257/678

(57) ABSTRACT

A probe card interposer includes a substrate with a plurality of conductive bumps disposed on first surface of the substrate. Each conductive bump comprises a dielectric core and a plurality of conductive leads. The suspended ends of the conductive wires extend toward the centers of the corresponding dielectric cores and are elastically supported by the corresponding dielectric cores. Therefore, the interposer can be installed between a probe head and a multi-layer PCB to make good electrical contacts to the probe head through the conductive bumps. In the embodiment, a plurality of symmetric conductive bumps are disposed on second surface of the substrate and are electrically connected to the conductive bumps on first surface of the substrate through vias or conductive posts. The conductive bumps can electrically contact the multi-layer PCB.

### FIELD OF THE INVENTION

The present invention relates to a modularized probe card, and more particularly, to an interposer for modularized probe cards.

### BACKGROUND OF THE INVENTION

During the fabrication of integrated circuits (IC), either in wafer form or package form, testing is required to ensure ICs in good electrical functions. However, since the circuit design of ICs becomes more complicated, only a probe card with high density of probes can fully test the electrical functions of the ICs and precisely screen out all the failed ICs. Moreover, a probe card with capable circuit designs and good probe mechanical and electrical characteristics will provide accurate testing results without underkill or overkill.

An IC tester comprises a test head for installing a probe card which serves as an electrical contact medium between a tester and Dies Uunder Test (DUT). Under the consideration of lower manufacturing costs, a probe card is modularized and comprises a multi-layer PCB, a probe head, and an interposer disposing between PCB and the probe head.

As revealed in U.S. Pat. No. 5,974,662, an interposer includes a substrate and a plurality of interconnection elements. Each interconnection element comprises a S-shaped core and a hard shell. The core is made of soft metals (such as gold) and the shell is made of plated hard metals (such as nickel or copper) coating over the core. When the interposer is installed between a PCB and a probe head, the tips of the interconnection elements of the interposer are difficult to control to precisely contact with fine pitch pads on the PCB or the probe head to make electrical connections. Accordingly, the shifting of the tips of the interconnection elements is a problem due to lack of firm support.

As revealed in R.O.C. Taiwan publication patent No. 493,756 entitled “Universal probe card for wafer-level testing”, an universal probe card includes an interposer, a PCB, and a probe head. The first surface of the interposer comprises a plurality of first probes and the other surface a plurality of second probes. The pitches between the first probes and the pitches between the second probes are fixed. The PCB comprises multi-layer circuits and is interchangeable in a probe card. One surface of the PCB is connected to a tester through pogo pads. Formed in the other surface of the PCB are a plurality of first through holes for electrical connections to the first probes of the interposer. The probe head includes multi-layer circuits and is also interchangeable. Formed in one surface of the probe head are a plurality of second through holes for electrical connections to the second probes of the interposer. Formed on the other surface are a plurality of probes. However, during the assembly of a probe card, the first probes and the second probes of the interposer are vulnerable to bending or breaking.

### SUMMARY OF THE INVENTION

A main purpose of the present invention is to provide a probe card interposer which comprises a substrate with a plurality of conductive bumps. Each conductive bump further includes a dielectric core and a plurality of contact wires. One ends of the contact wires are bonded to the bonding pads of the substrate adjacent to the corresponding dielectric cores. The other ends of the contact wires are suspended and extend toward the centers of the corresponding dielectric cores such that the contact wires are elastically supported by the corresponding dielectric cores. Therefore, the interposer can possesses the capability of elastic and electrical contact with the probe head and the multi-layer PCB to assemble a modularized probe head to resolve the common issues of an interposer for poor coplanarity leading to electrically open and excessive stresses leading to breaking of the electrical contacts. Moreover, since the dielectric bumps are elastic and the contact wires are supported by the dielectric cores, the contact wires manufactured by MEMS or wire bonding can achieve accurate electrical contact with good mechanical strengths.

A second purpose of the present invention is to provide a probe card interposer with a plurality of conductive bumps disposed on the upper and lower surfaces of the substrate. Each conductive bump includes a dielectric core and a plurality of contact wires, wherein one ends of the contact wires are suspended and extend toward the centers of the corresponding dielectric cores such that the contact wires can be elastically supported by the corresponding dielectric cores. The contact wires on the upper surface are vertically aligned with and electrically connected to the corresponding contact wires on the lower surface through a plurality of corresponding vias or conductive posts in the substrate. Therefore, the interposer can electrically contact the multi-layer PCB and the probe head at the same time in the vertical direction.

A third purpose of the present invention is to provide a probe card interposer with bonding pads formed on the upper and the lower surfaces of the substrate, where the bonding pads are electrically connected through vias. A plurality of contact wires formed by wire bonding are disposed on the corresponding bonding pads, each having a suspended ends extending toward the centers of the corresponding bonding pads to form a plurality of elastic conductive bumps.

A probe card interposer according to the present invention comprises a substrate and a plurality of first conductive bumps. The substrate has a first surface and a corresponding second surface, where the first conductive bumps are disposed on the first surface. Each first conductive bump includes a dielectric core and a plurality of contact wires. Each contact wire has a fixed end and a suspended end. The fixed ends are bonded to the first surface adjacent to the corresponding dielectric cores on the substrate. The suspended ends of the contact wires extend toward the centers of the corresponding dielectric cores such that the contact wires can be elastically supported by the dielectric cores.

### DESCRIPTION OF THE DRAWINGS

FIG. 1 is a cross-sectional view of a probe card according to the first embodiment of the present invention.

FIG. 2 is a partial cross-sectional view of the probe card interposer according to the first embodiment of the present invention.

FIG. 3 is a cross-sectional view of a probe card according to the second embodiment of the present invention.

FIG. 4 is a partial cross-sectional view of the probe card interposer according to the second embodiment of the present invention.

FIG. 5 is a partial top view of the probe card interposer according to the second embodiment of the present invention.

FIG. 6 is a partial cross-sectional view of the probe card interposer according to the third embodiment of the present invention.

FIG. 7 is a partial top view of the probe card interposer according to the third embodiment of the present invention.

### DETAIL DESCRIPTION OF THE INVENTION

Please refer to the attached drawings, the present invention will be described by means of an embodiment below.

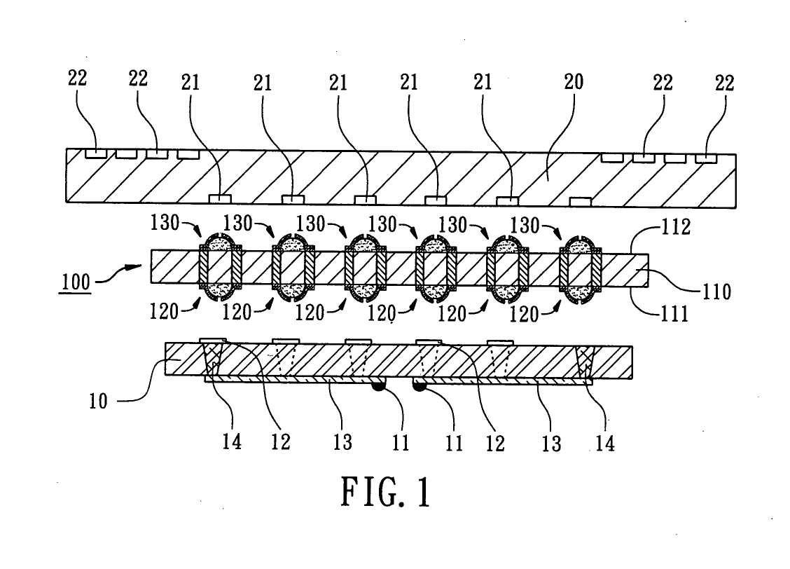

The first embodiment according to present invention, as shown in FIG. 1, a probe card interposer 100 is configured for disposing between a probe head 10 and a multi-layer PCB 20 to assemble a modularized probe card. The probe head 10 is made of Si wafers, ceramic substrates, or glass substrates. The probe head 10 has a plurality of probing components 11 such as probes or bumps for probing the bonding pads of ICs, where the probing components 11 are electrically connected to the contact pads 12 on the other surface of the probe head 10 through dedicated circuits 13 and vias 14. The multi-layer PCB 20 has a plurality of contact pads 21 and a plurality of pogo pads 22, where the contact pads 21 are electrically connected to the contact pads 12, and the pogo pads 22 are configured to connect the corresponding pogo pins on the test head of a tester (not shown in the drawings).

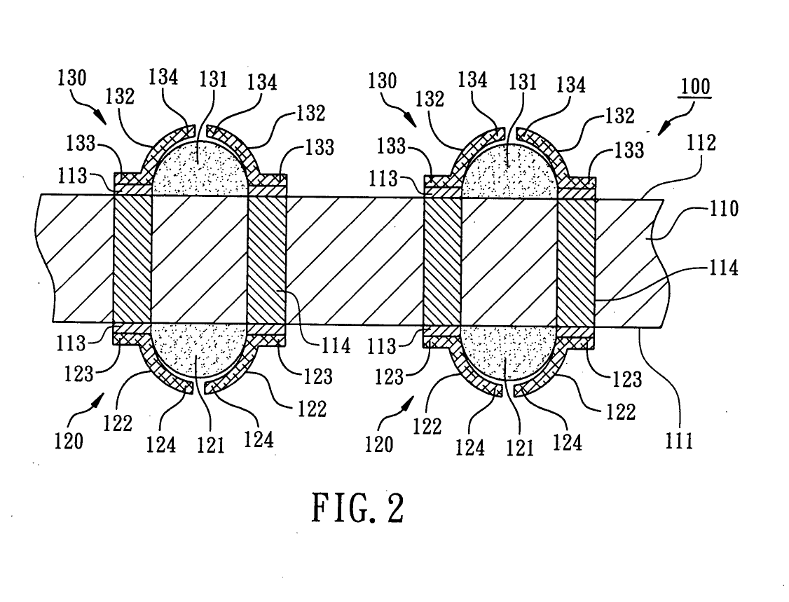

As shown in FIG. 2, the interposer 100 includes a substrate 110 and a plurality of first conductive bumps 120 disposed on the first surface 111 of the substrate 110. The first conductive bumps 120 are arranged in a grid array for elastically and electrically connecting to the contact pads 12 of the probe head 10. Preferably, the interposer 100 further includes a plurality of second conductive bumps 130 disposed on the second surface 112 of the substrate 110 for elastically and electrically connecting to the contact pads 21 of the PCB 20. Each first conductive bump 120 has a first dielectric core 121 and a plurality contact wires 122, where the first contact wires 122 are electrically connected to the second contact wires 132 of the second conductive bumps 130 in the vertical direction through the vias 114 in the substrate 110. The substrate 110 can be selected from a group of ceramic substrates, glass substrates, or Si wafers. The substrate 110 includes a plurality of bonding pads 113 on the first surface 111 and on the second surface 112. According to the present embodiment, the first dielectric core 121 is selected from a group of silicon gel, rubber, or other elastic materials and can be formed by printing or photolithography. The thickness of the first dielectric cores 121 ranges from 30 μm to 500 μm, preferably from 60 μm to 180 μm. Each contact wire 122 has a first fixed end 123 and a suspended end 124, where the fixed ends 123 are bonded to the bonding pads 113 on the first surface 111 adjacent to the corresponding first dielectric cores 121. The suspended ends 124 extend toward the centers of the corresponding dielectric cores 121 such that the first contact wires 122 can be elastically supported by the corresponding first dielectric cores 121 to suspend away from the first surface 111 of the substrate 110. The contact wires 122 are probes made by Micro-Electro-Mechanical-System (MEMS), or made by wire bonding and plating technology. The contact wires 122 are made from a group of nickel, gold, copper, tungsten, or their alloys. In the present embodiment, the first contact wires 122 have a coefficient of thermal expansion (CTE) of 10 to 30×10⁻⁶ (^{o}C⁻¹). Therefore, the first conductive bumps 120 have the characteristics of good electrical contact with elasticity, good coplanarity, good mechanical strength, long contact life time, and without position shift and is suitable to be an interposer for a modularized probe card.

Preferably, the first dielectric core 121 has an inclined slope for the extension of the first contact wires 122. Moreover, there is a gap between 0.05 μm and 0.51 μm existing between the first dielectric cores 121 and the corresponding first contact wires 122.

The second conductive bumps 130 on the second surface 112 of the substrate 110 are vertically aligned with the first conductive bumps 120 for easy manufacture with lower costs. The structure of the second conductive bumps 130 can be the same as the first conductive bumps 120 or different. In the present embodiment, each second conductive bump 130 includes a second dielectric core 131 and a plurality of second contact wires 132. Each second contact wire 132 has a second fixed end 133 and a second suspended end 134, where the second fixed ends 133 are bonded to the bonding pads 113 on the second surface 112. The second suspended ends 134 extend toward the centers of the corresponding second dielectric cores 131 such that the second contact wires 132 can be elastically supported by the corresponding second dielectric cores 131. The CTE of the second contact wires 132 may be the same as the first contact wires 122.

The temperatures in the testing environment may be dramatically changed from room temperature up to 125° C. or −40° C. up to room temperature. The first dielectric cores 121 and the second dielectric cores 131 will expand due to the dramatic temperature changes and will push the first contact wires 122 and the second contact wires 132 outward. However, the gaps between the first contact wires 122 and the first dielectric cores 121 and the gaps between the second contact wires 132 and the second dielectric cores 131 will absorb the expansion and become smaller due to the dramatic temperature changes in the testing environment. Therefore, the first contact wires 122 and the second contact wires 132 still can precisely electrically contact with the contact pads 12 of the probe head 10 and the contact pads 21 of the multi-layer PCB 20. Good electrical contacts between the probe head 10 and the multi-layer PCB 20 can be achieve even under dramatic temperature changes.

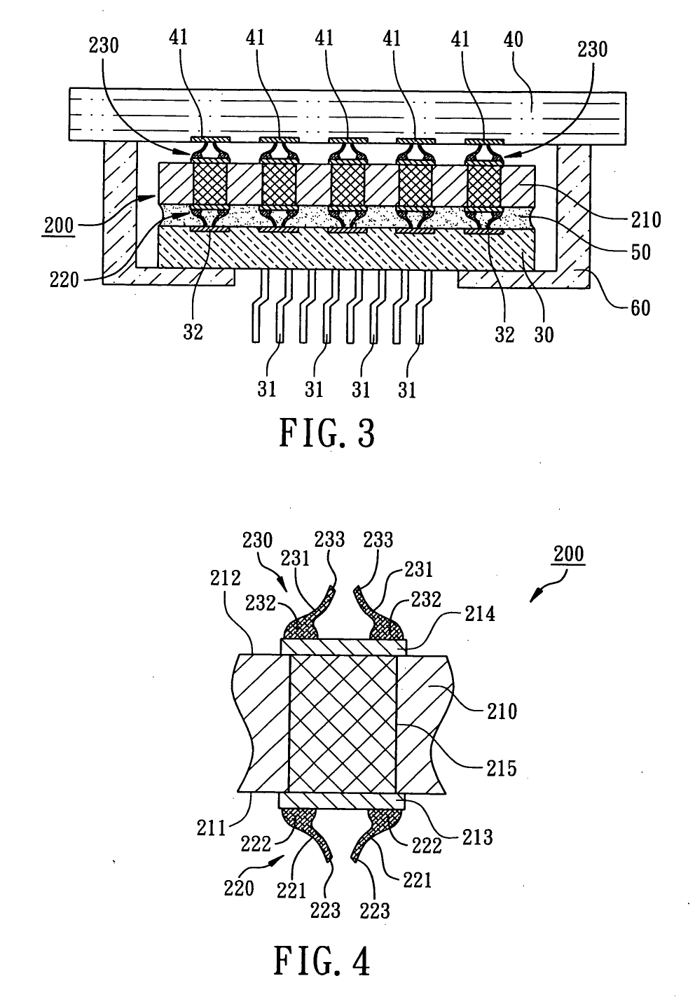

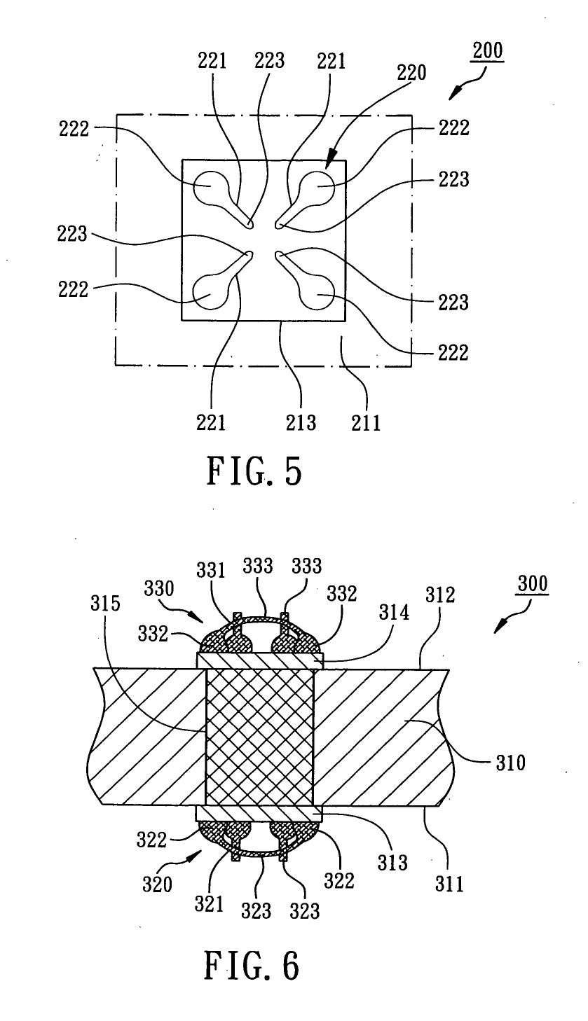

According to the second embodiment of the present invention, as shown in FIG. 3, a modularized probe card comprises a probe head 30, a multi-layer PCB 40 and an interposer 200 disposed between the probe head 30 and the multi-layer PCB 40. A plurality of probes 31 are disposed on one surface of the probe head 30 and a plurality of contact pads 32 on the other surface of the probe head 30. A plurality of contact pads 41 are disposed on one surface of the multi-layer PCB 40 and are electrically connected to the contact pads 32 of the probe head 30 by the interposer 200. The interposer 200 and the probe head 30 can be joined together to be a one-piece component by disposing and curing the underfill material 50 between the interposer 200 and the probe head 30 to ensure good electrical contacts between both. A fixture is used to fix the one-piece component including the interposer 200 and the probe head 30 to the multi-layer PCB 40 to reduce the alignment errors.

As shown in FIG. 4, the interposer 200 includes a substrate 210, a plurality of first conductive bumps 220 and a plurality of second conductive bumps 230. The substrate 210 has a first surface 211 and a corresponding second surface 212. The substrate 210 further includes a plurality of first bonding pads 213 on the first surface 211, a plurality of second bonding pads 214 on the second surface 212, and a plurality of conductive posts 215 or vias. The conductive posts 215 vertically and electrically connect the first bonding pads 213 and the second bonding pads 214. In the present embodiment, the dimensions of the first bonding pads 213 and the second bonding pads 214 are larger than the diameters of the corresponding conductive posts 215 to fully cover the conductive posts 215. The first conductive bumps 220 are disposed on the first bonding pads 213, and the second conductive bumps 230 on the second bonding pads 214, where the second conductive bumps 230 are vertically aligned with the first conductive bumps 220. Each first conductive bump 220 includes a plurality of the first contact wires 221 formed by wire bonding. Each first contact wire 221 has a first fixed end 222 and a suspended end 223, where the first fixed ends 222 are bonded to the corresponding first bonding pads 213, and the suspended ends 223 extend toward the centers of the bonding pads 213. Moreover, the suspended height between the suspended ends 223 of the first contact wires 221 and the first bonding pads 213 are between 60 μm and 180 μm so that the first contact wires 221 can elastically and electrically contact the contact pads 32 of the probe head 30. Preferably, the fixed ends 222 of the first contact wires 221 are bonded to the edges or the corners of the corresponding first bonding pads 213, and the suspended ends 223 extend toward the centers of the first bonding pads 213 to ensure good electrical contact.

Furthermore, in the same way, each second contact wire 231 has a second fixed end 232 and a second suspended end 233, where the second fixed ends 232 are bonded to the edges or the corners of the second bonding pads 214, and the second suspended ends 233 extend toward the centers of the corresponding second bonding pads 214. Therefore, the second contact wires 223 can elastically and electrically contact the contact pads 41 of the multi-layer PCB 40.

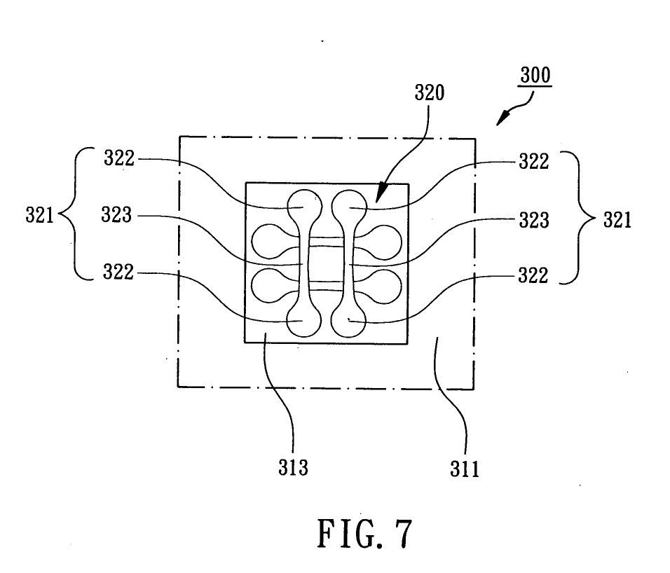

According to the third embodiment of the present invention, as shown in FIG. 6 and FIG. 7, a probe card interposer 300 includes a substrate 310, a plurality of first conductive bumps 320 and a plurality of second conductive bumps 330. The substrate 310 has a first surface 311 and a second surface 312. The substrate includes a plurality of bonding pads 313 on the first surface 311, a plurality of second bonding pads 314 on the second surface 312, and a plurality of conductive posts 315. The first bonding pads 313 are electrically connected to the second bonding pads 314 through the conductive posts 315. The first conductive bumps 320 are disposed on the first bonding pads 313, and the second conductive bumps 330 on the second bonding pads 314. The second conductive bumps 330 are vertically aligned with the first conductive bumps 320. Each first conductive bump 320 includes a plurality of first contact wires 321 formed by wire bonding. Each first conductive wire 321 has two first fixed end 322 and a first suspended portion 323, where the first fixed ends 322 are bonded to the corresponding bonding pads 313, and the first suspended portions 323 extend across the centers of the corresponding bonding pads 313. Therefore, the first conductive bumps 320 can elastically and electrically contact a probe head. Similarly, each second conductive bump 330 includes a plurality of second contact wires 331 formed by wire bonding, and each second contact wire 331 has two second fixed ends 332 and a suspended portion 333, where the second fixed ends 332 are bonded to the corresponding bonding pads 314, and the second suspended portions 333 extend across the centers of the corresponding bonding pads 314. Therefore, the second conductive bumps 330 can elastically and electrically contact to a multi-layer PCB.

The above description of embodiments of this invention is intended to be illustrative and not limiting. Other embodiments of this invention will be obvious to those skilled in the art in view of the above disclosure.

What is claimed is:

1. A probe card interposer for being installed between a multi-layer PCB and a probe head, comprising:
a substrate having a first surface and a second surface; and
a plurality of first conductive bumps disposed on the first surface, each first conductive bump including a first dielectric core and a plurality of first contact wires, each first contact wire having a first fixed end and a first suspended end, wherein the first fixed ends are bonded to the first surface adjacent to the corresponding first dielectric cores, and the first suspended ends extend toward the centers of the corresponding first dielectric cores such that the first contact wires can be elastically supported by the corresponding first dielectric cores.

2. The probe card interposer of claim 1, wherein the gap between the first suspended ends and the corresponding first dielectric core ranges from 0.05 μm to 0.5 μm.

3. The probe card interposer of claim 1, further comprising a plurality of second conductive bumps disposed on the second surface of the substrate to be aligned with the first conductive bumps.

4. The probe card interposer of claim 3, wherein each second conductive bump includes a second dielectric core and a plurality of second contact wires, wherein each second contact wire has a second fixed end and a second suspended end, wherein the second fixed ends are bonded to the second surface of the substrate and the second suspended ends extend toward the centers of the corresponding second dielectric cores such that the second contact wires are elastically supported by the corresponding second dielectric cores.

5. The probe card interposer of claim 4, wherein the substrate has a plurality of vias for electrical connections between the first contact wires and the second contact wires.

6. The probe card interposer of claim 1, wherein the first contact wires are MEMS probes.

7. The interposer of claim 1, wherein the first dielectric core is selected from a group of silicone gel and rubber.

8. The probe card interposer of claim 1, wherein the thickness of the first dielectric core ranges from 60 μm to 180 μm.

9. The probe card interposer of claim 1, wherein the first conductive bumps are arranged in a grid array.

10. The probe card interposer of claim 1, wherein the first contact wires are formed by wire bonding.

11. A probe card interposer comprising:
a substrate having a first surface and a second surface, the substrate including a plurality of first bonding pads on the first surface, a plurality of second bonding pads on the second surface, and a plurality of conductive posts electrically connecting the first bonding pads and the second bonding pads; and
a plurality of first conductive bumps disposed on the first bonding pads of the substrate, each first conductive bump including a plurality of first contact wires formed by wire bonding, wherein each first contact wire has a suspended end extending toward the centers of the corresponding first bonding pads.

12. The probe card interposer of claim 11, wherein the height between the suspended ends of the first contact wires and the corresponding first bonding pads ranges from 60 μm to 180 μm.

13. The probe card interposer of claim 11, wherein the dimension of the contact pads is larger than the corresponding diameter of the conductive posts to cover the conductive posts.

14. The probe card interposer of claim 11, further comprising a plurality of second conductive bumps disposed on the second bonding pads of the substrate and vertically aligned with the first conductive bumps.

15. The probe card interposer of claim 14, wherein each second conductive bump includes a plurality of second contact wires formed by wire bonding, each has a suspended end extending toward to the centers of the corresponding second bonding pads.

16. A probe card interposer comprising:
a substrate having a first surface and a second surface, the substrate including a plurality of first bonding pads on the first surface, a plurality of second bonding pads on the second surface, wherein the first bonding pads are electrically connected to and aligned with the corresponding second bonding pads; and
a plurality of first conductive bumps disposed on the first bonding pads of the substrate, each first conductive bump including a plurality of first contact wires formed by wire bonding, wherein each first contact wire has two first fixed ends bonded to the first bonding pads and a first suspended portion extending across the centers of the corresponding first bonding pads.

17. The probe card interposer of claim 16, further comprising a plurality of second conductive bumps disposed on the second bonding pads of the substrate.

18. The probe card interposer of claim 17, wherein each second conductive bump includes a plurality of second contact wires formed by wire bonding, wherein each second contact wire has two second fixed ends bonded to the second bonding pads and a second suspended portion extending across the centers of the corresponding second bonding pads.
